(19) United States
(12) Patent Application Publication
(10) Pub. No.: US 2009/0296514 A1
(43) Pub. Date: Dec. 3, 2009

(54) METHOD FOR ACCESSING A MEMORY CHIP

(76) Inventor: Chih-Hui Yeh, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/128,618

(22) Filed: May 29, 2008

(51) Int. Cl. G11C 8/00

(52) U.S. Cl. 365/233.1; 365/230.01

(57) ABSTRACT

The present invention provides a method for accessing a memory chip. The method includes: positioning a plurality of first input pins and a plurality of second input pins on the memory chip; respectively inputting a plurality of row address signals into the plurality of first input pins, where a length of a row address command package of each row address signal corresponds to a plurality of clock periods of a clock signal, and the row address command package includes a plurality of row input commands; and respectively inputting a plurality of column address signals into the plurality of second input pins, where a length of a column address command package of each column address signal corresponds to a plurality of clock periods of the clock signal, and the column address command package includes a plurality of column input commands.

### BACKGROUND OF THE INVENTION

1. Field of the Invention

The present invention relates to a method for accessing a memory chip, and more particularly, to a memory accessing method capable of reducing a number of input pins of a dynamic random access memory (DRAM).

2. Description of the Prior Art

Regarding the prior art double data rate (DDR) synchronous DRAM (SDRAM) architecture, a SDRAM typically has following input signals: two clock signals, i.e. CLK and #CLK, sixteen memory address input signals: A0-A15, four bank address input signals: BA0-BA3, a chip-select signal CS, a row address strobe signal RAS, a column address strobe signal CAS, a write enable signal WE, a synchronous signal CKE, a calibration signal ZQ, and a reset signal RESET. The length of an input command of each input signal mentioned above corresponds to a clock period of a clock signal, and each input signal is inputted into a memory chip through its own pin, which is dedicated for the input signal. Therefore, the memory chip of the prior art SDRAM typically has twenty-nine input pins.

Please refer to FIG. 1. FIG. 1 is a diagram illustrating a prior art dual in-line memory module (DIMM) 100. As shown in FIG. 1, the DIMM 100 comprises eight memory chips 110_1-110_8, and each memory chip comprises twenty-nine input pins. Regarding the operations of the DIMM 100, twenty-nine input signals are transmitted from a controller 120 to the memory chip 100_1, then the input signals sequentially transmit to the memory chip 110_2, 110_3, . . . , 110_8. Therefore, two adjacent memory chips are connected each other with twenty-nine electrical wirings. Generally speaking, the more input pins the memory chip has, the narrower the distance between two electrical wirings, causing increased difficulty of the layout of the electrical wirings and increased interference between signals transmitted through the electrical wirings. Therefore, the layout of the DIMM 100 is difficult due to these disadvantages. Additionally, regarding the test of the memory chips implemented as DIMMs, the tooling cost appears to be too high, and the number of memory chips that a test station can test each time appears to be insufficient.

### SUMMARY OF THE INVENTION

It is therefore an objective of the present invention to provide a method for accessing a memory chip with the method being capable of reducing a number of input pins of a memory such as a dynamic random access memory (DRAM), in order to reduce the density of electrical wirings of dual in-line memory modules (DIMMs) and save the cost on tests of memory chips.

According to one embodiment of the present invention, a method for accessing a memory chip is provided. The method comprises: positioning a plurality of first input pins and a plurality of second input pins on the memory chip; respectively inputting a plurality of row address signals into the plurality of first input pins, where a length of a row address command package of each row address signal corresponds to a plurality of clock periods of a clock signal, and the row address command package comprises a plurality of row input commands; and respectively inputting a plurality of column address signals into the plurality of second input pins, where a length of a column address command package of each column address signal corresponds to a plurality of clock periods of the clock signal, and the column address command package comprises a plurality of column input commands.

According to the method for accessing the memory chip provided by the present invention, the number of input pins of the memory chip can be reduced without influencing the performance of the memory implemented with the memory chip, causing the layout of the DlMMs to be easier and the testing cost to be lowered.

These and other objectives of the present invention will no doubt become obvious to those of ordinary skill in the art after reading the following detailed description of the preferred embodiment that is illustrated in the various figures and drawings.

### BRIEF DESCRITPION OF THE DRAWINGS

FIG. 1 is a diagram illustrating a prior art dual in-line memory module (DIMM).

FIG. 2 is a diagram illustrating a memory chip according to one embodiment of the present invention.

FIG. 3 is a diagram illustrating six row address signals according one embodiment of the present invention.

FIG. 4 is a diagram illustrating five column address signals according one embodiment of the present invention.

FIG. 5 is a diagram illustrating an exemplary operation of accessing the memory chip shown in FIG. 2.

### DETAILED DESCRIPTION

In the prior art DDR SDRAM architecture, a length of an input command of each input signal corresponds to a clock period of a clock signal, and each input signal is inputted into a memory chip through its own pin. Therefore, the prior art memory chip has twenty-nine input pins. In order to reduce a number of input pins, the present invention uses the concept of the “command package”. That is, each pin is utilized for receiving a command package, and the command package comprises a plurality of input commands such as four input commands. Thus, the number of input pins of a memory chip implemented according to the present invention can be reduced. However, because each command package comprises four input commands and the length of an input command corresponds to a clock period, the length of a command package is corresponding to four clock periods. In the operations of the memory, the row address signal and the column address signal cannot be inputted into the same bank at the same time. As a result, when using the command package whose length is four clock periods, it is required for the conventional architecture to wait for four clock periods after the row address signal is inputted into a bank and then the column address signal can be inputted into the same bank, causing the performance of the memory to be seriously degraded.

Therefore, the present invention provides a method which can reduce the number of input pins of a memory chip without seriously degrading the performance of the memory. The operations are described as follows.

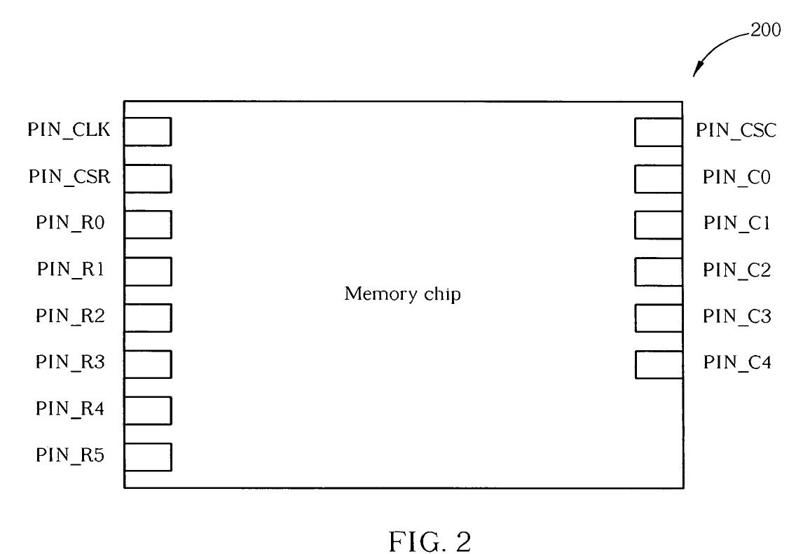

Please refer to FIG. 2. FIG. 2 is a diagram illustrating a memory chip 200 according to one embodiment of the present invention. As shown in FIG. 2, the memory chip 200 comprises a clock pin PIN_CLK, six row address signal pins PIN_R0-PIN_R5, five column address signal pins PIN_C0-PIN_C4, a first chip-selection signal pin PIN_CSR for a chip-select signal such as a row address chip-select signal, and a second chip-select signal pin PIN_CSC for a chip-select signal such as a column address chip-select signal. In this embodiment, the clock signal pin PIN_CLK is utilized for receiving a clock signal CLK, the row address signal pins PIN_-R0-PIN_R5 are utilized for respectively receiving six row address signals RowAdr0, RowAdr1, RowAdr2, RowAdr3, RowAdr4, RowAdr5, the column address signal pins PIN_C0-PIN_C5 are utilized for respectively receiving five column address signals ColAdr0, ColAdr1, ColAdr2, ColAdr3, ColAdr4, the first chip-select signal pin PIN_CSR (i.e. the row address chip-select signal pin) is utilized for receiving a first chip-select signal CSR to select the memory chip 200 to receive the row address signals, and the second chip-select signal pin PIN_CSC (i.e. the column address chip-select signal pin) is utilized for receiving a second chip-select signal CSC to select the memory chip 200 to receive the column address signals. Please note that, the pins positioned on the memory chip 200 shown in FIG. 2 is for illustrative purposes only. In addition, without influencing the disclosure of the present invention, FIG. 2 only shows a portion of the pins related to further description of the present invention. In practice, the memory chip 200 of the present invention is not limited to have the same pin arrangement as that shown in FIG. 2. The accessing operations of the memory chip 200 are described as follows.

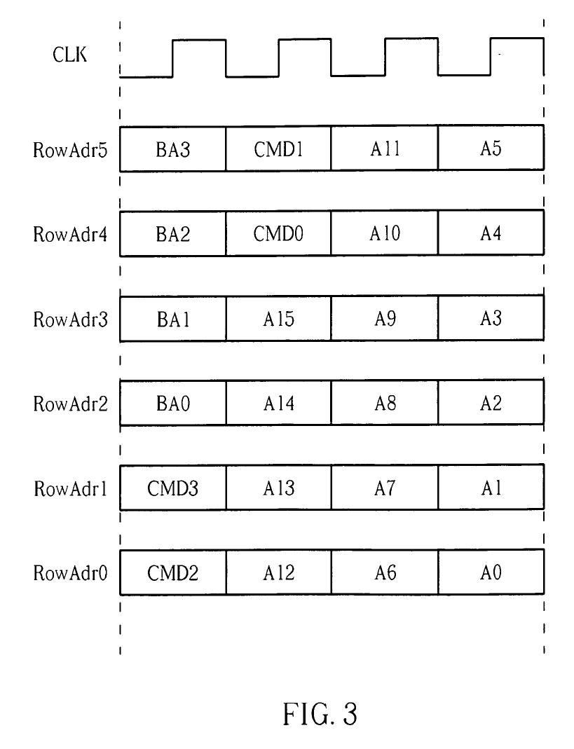

Please refer to FIG. 3. FIG. 3 is a diagram illustrating six row address signals according one embodiment of the present invention. In the present invention, six row address signals RowAdr0, RowAdr1, RowAdr2, RowAdr3, RowAdr4, RowAdr5 are inputted into the memory chip through six first input pins (i.e., row address signal pins PIN_R0-PIN_R5). As shown in FIG. 3, the length of a row address command package of each row address signal corresponds to four clock periods of the clock signal CLK, and the row address command package comprises four row input commands. Therefore, six row address command packages of the six row address signals comprise twenty-four row input commands. In this embodiment, the twenty-four row input commands comprises four pieces of setting information of bank address BA0-BA3, sixteen pieces of setting information of memory address A0-A15, and four pieces of memory control command setting information CMD0-CMD3, where the four pieces of setting information of bank address BA0-BA3 are implemented for replacing the bank address input signals BA0-BA3 in the prior art DDR SDRAM architecture, and the sixteen pieces of setting information of memory address A0-A15 are implemented for replacing the memory address input signals A0-A15 in the prior art DDR SDRAM architecture. In addition, the four pieces of memory control command setting information CMD0-CMD3 are decoded to generate a control command of a plurality of memory control commands, where the memory control commands may comprise an activate command, a pre-charge command, a refresh command, a mode register set (MRS) command, a self-refresh entry (SRE) command, a power down entry command, a ZQ calibration long/ZQ calibration short (ZQCL/ZQCS) command, . . . , etc.

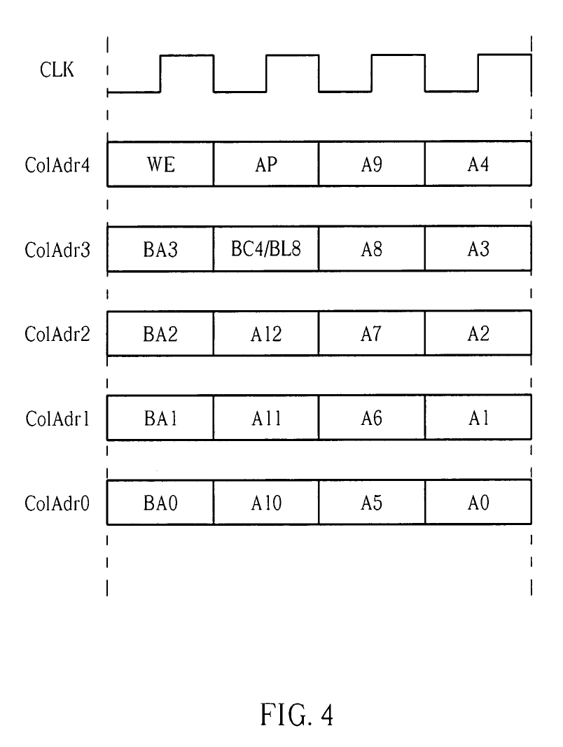

Please refer to FIG. 4. FIG. 4 is a diagram illustrating five column address signals according one embodiment of the present invention. In the present invention, the five column address signals ColAdr0, ColAdr1, ColAdr2, ColAdr3, ColAdr4 are inputted into the memory chip through the five second input pins (i.e., the column address signal pins PIN_C0-PIN_C4 shown in FIG. 2). As shown in FIG. 4, the length of a column address command package of each column address signal corresponds to four clock periods of the clock signal CLK, and the column address command package comprises four column input commands. Therefore, five column address command packages of the five column address signals comprise twenty column input commands. The twenty column input commands comprise four pieces of setting information of bank address BA0-BA3, thirteen pieces of setting information of memory address A0-A12, a write enable (WE) input command, an auto-pre-charge (AP) input command, and a burst chop 4/burst length 8 (BC4/BL8) input command. The four pieces of setting information of bank address BA0-BA3 are implemented for replacing the bank address input signals BA0-BA3 in the prior art DDR SDRAM architecture, and the thirteen pieces of setting information of memory address A0-A12 are implemented for replacing the memory address input signals A0-A12 in the prior art DDR SDRAM architecture.

It is noted that, the input commands of the six row address command packages of the six row address signals are for illustrative purposes only. In practice, the twenty-four row input commands can be rearranged and the twenty column input commands shown in FIG. 4 can also be rearranged without influencing the operations of the memory chip of the present invention. For example, locations of any two of the row input commands can be exchanged with each other, and locations of any two of the column input commands can also be exchanged with each other. In another example, locations of the row input commands can be rotated, and locations of the column input commands can be rotated, too. Additionally, the number of the above-mentioned row address signals (RowAdr0-RowAdr5), the number of the above-mentioned column address signals (ColAdr0-ColAdr4), and the number of pieces of the setting information of the bank address (BA0-BA3) are for illustrative purposes only. In practice, when the storage capacity of the memory is increased (e.g. the number of pieces of setting information of the memory address is increased, or the number of the banks is increased), seven or more row address signals can be used, and six or more column address signals can be used. For example, the memory chip 200 may further comprises a row address signal pin PIN_R6 and a column address signal pin PIN_C5, where the row address signal pin PIN_R6 is utilized for receiving a row address signal RowAdr6, and a row address command package of the row address signal RowAdr6 comprises two pieces of setting information of the bank address BA4, BA5, and two pieces of setting information of the memory address A16, A17; and a column address command package of the column address signal ColAdr5 comprises two pieces of setting information of the bank addresses BA4, BA5, and two pieces of setting information of the memory addresses A13, A14. As mentioned above, because the row (column) address command package of this embodiment comprises four row (column) input commands, adding only one additional row address signal pin and only one additional column address signal pin in a variation of this embodiment can increase four pieces of setting information of the bank address or the memory address. Therefore, the testing cost of the memory chip can be reduced.

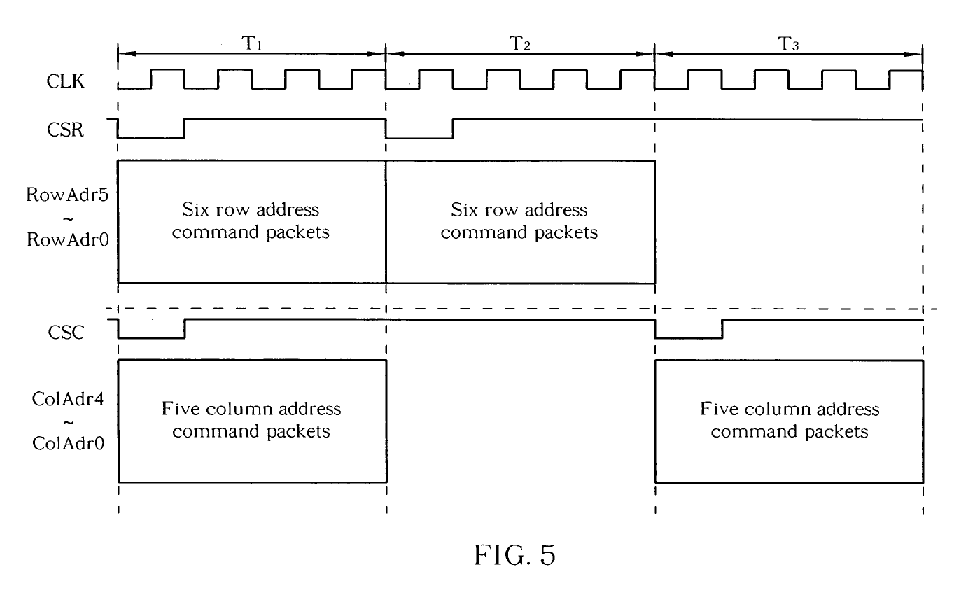

As mentioned above, both the row address signals and the column address signals comprise the setting information of the memory address (A0, A1, . . . , etc.), and therefore, different banks can be operated at the same time. FIG. 5 is a diagram illustrating an exemplary operation of accessing the memory chip shown in FIG. 2. As shown in FIG. 5, at time T1, six row address command packages of the six row address signals RowAdr0-RowAdr5 are utilized for activating a first bank of the memory chip 200, and at the same time, five column address command packages of the five column address signals ColAdr0-ColAdr4 are utilized for writing a second bank (if the second bank is activated). At time T2, six row address command packages of the six row address signals RowAdr0-RowAdr5 are utilized for activating a third bank. At time T3, five column address command packages of the five column address signals ColAdr0-ColAdr4 are utilized for reading the first bank. Therefore, the performance degradation of the memory due to the command package whose length is four clock periods can be alleviated.

In the prior art DDR SDRAM architecture, many parameters such as RAS to RAS delay time tRRD, RAS pre-charge time tRP, RAS to CAS delay time tRCD, row cycle time tRC, . . . , etc. have prescribed values. If the clock period of the memory is equal to 1.25 nano-seconds, the lengths of the row address command package and the column address command package provided by the present invention are equal to 5 nano-seconds, which can be utilized for appropriately replacing related operations of the prior art DDR SDRAM architecture without violating the prescribed values of the related parameters. For example, the RAS pre-charge time tRP is at least 10 nano-seconds, and is equal to the length of two row address command packages. That is, a length of an interval between a pre-charge operation and an activation operation of a bank is equal to the length of the row address command package. Therefore, the performance of the memory will not be influenced.

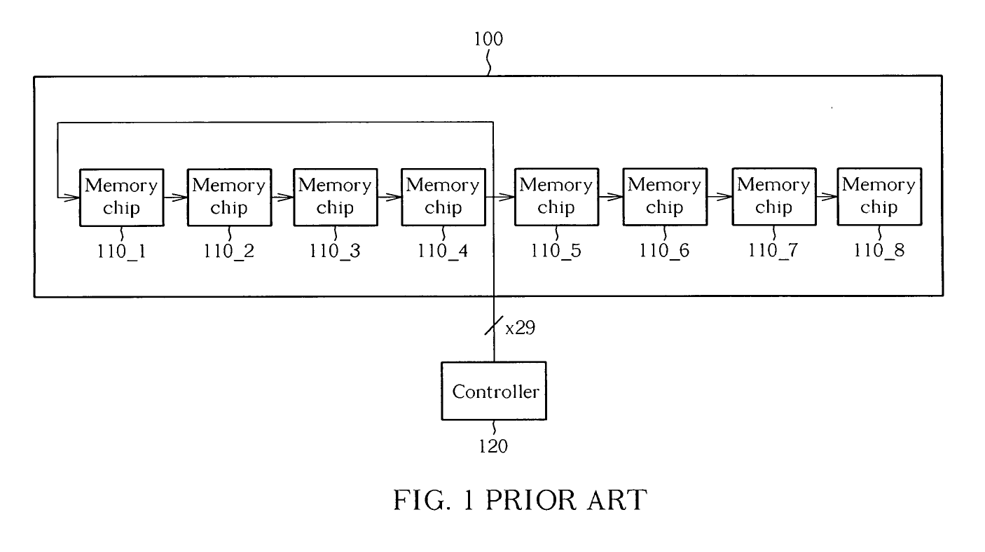

In addition, the prior art DDR SDRAM architecture has a chip-select signal utilized for enabling a memory chip. In the present invention, because both the six row address signals and the five column address signals comprise the setting information of the memory address, the present invention further provides a first chip-select signal CSR (i.e. the row address chip-select signal) utilized for enabling the memory chip to receive the row address signals, and a second chip-select signal CSC (i.e. the column address chip-select signal) utilized for enabling the memory chip to receive the column address signals. The row address chip-select signal CSR and the column address chip-select signal CSC are inputted into the memory chip through a third input pin (i.e., the first chip-select signal pin PIN_CSR shown in FIG. 1) and a fourth input pin (i.e., the second chip-select signal pin PIN_CSC shown in FIG. 1), respectively. As shown in FIG. 5, when the row address chip-select signal CSR or the column address chip-select signal CSC is at an enabling state, the memory chip can receive the row address signals or the column address signals.

Briefly summarizing the above method for accessing the memory chip, in the embodiment of the present invention, the lengths of the six row address command packages of the six row address signals are equal to four clock periods, and each row address command package comprises four row input commands; and the lengths of the five column address command packages of the five column address signals are equal to four clock periods, and each column address command package comprises four row input commands. Counting the eleven address input signals mentioned above, the two clock signals CLK and #CLK, the row address chip-select signal CSR, the column address chip-select signal CSC, an on-die termination signal ODT, a synchronous signal CKE, a calibration signal ZQ, and a reset signal RESET, the method for accessing the memory chip provide by the embodiment of the present invention needs nineteen input signals. That is, the memory chip only requires nineteen input pins. In contrast to the prior art memory chip having twenty-nine input pins, the present invention indeed reduce the input pins of the memory chip. Therefore, the layout of the DIMM is easier, and the testing cost can also be reduced.

Those skilled in the art will readily observe that numerous modifications and alterations of the device and method may be made while retaining the teachings of the invention.

What is claimed is:

1. A method for accessing a memory chip, comprising:
positioning a plurality of first input pins and a plurality of second input pins on the memory chip;
respectively inputting a plurality of row address signals into the plurality of first input pins, where a length of a row address command package of each row address signal corresponds to a plurality of clock periods of a clock signal; and
respectively inputting a plurality of column address signals into the plurality of second input pins, where a length of a column address command package of each column address signal corresponds to a plurality of clock periods of the clock signal.

2. The method of claim 1, wherein the row address command packet comprises a plurality of row input commands, and the column address command package comprises a plurality of column input commands.

3. The method of claim 2, wherein the length of the row address command package corresponds to four clock periods, and the row address command package comprises four row input commands.

4. The method of claim 3, wherein quantity of first input pins is six.

5. The method of claim 4, wherein the row input commands of the six row address command packages of the six row address signals comprises four pieces of setting information of bank address, sixteen pieces of setting information of memory address, and four pieces of memory control command setting information.

6. The method of claim 5, further comprising:
decoding the four pieces of memory control command setting information of to generate a memory control command.

7. The method of claim 2, wherein the length of the column address command package corresponds to four clock periods, and the column address command package comprises four column input commands.

8. The method of claim 7, wherein quantity of second input pins is five.

9. The method of claim 8, wherein the column input commands of the five column address command packages of the five column address signals comprises at least four pieces of setting information of bank address and thirteen pieces of setting information of memory address.

10. The method of claim 8, wherein the column input commands of the five column address command packages of the five column address signals comprises at least a write enable (WE) input command, a auto-precharge (AP) input command, and a burst chop/burst length (BC/BL) input command.

11. The method of claim 1, further comprising:
positioning a third input pin and a fourth input pin on the memory chip;
inputting a first chip-select signal to the third input pin into utilize the memory chip to receive the plurality of row address signals; and
inputting a second chip-select signal to the fourth input pin into utilize the memory chip to receive the plurality of column address signals.
